(19) United States
(12) Patent Application Publication
(10) Pub. No.: US 2013/0092950 A1
(43) Pub. Date: Apr. 18, 2013

(54) NITRIDE SEMICONDUCTOR GROWTH SUBSTRATE AND MANUFACTURING METHOD OF THE SAME, NITRIDE SEMICONDUCTOR EPITAXIAL SUBSTRATE AND NITRIDE SEMICONDUCTOR ELEMENT

(71) Applicants: Hajime FUJIKURA, Mito (JP); Michiko Matsuda, Arakawa-ku (JP); Taichiroo Konno, Hitachi (JP)

(72) Inventors: Hajime FUJIKURA, Mito (JP); Michiko Matsuda, Arakawa-ku (JP); Taichiroo Konno, Hitachi (JP)

(73) Assignee: Hitachi Cable, Ltd., Tokyo (JP)

(21) Appl. No.: 13/615,421

(22) Filed: Sep. 13, 2012

(30) Foreign Application Priority Data
Oct. 17, 2011 (JP) 2011-228307

(51) Int. Cl. H01L 29/20; H01L 21/20

(52) U.S. Cl. 257/76; 438/478; 257/E29.089; 257/E21.09

(57) ABSTRACT

A nitride semiconductor growth substrate includes a principal surface including a C-plane of a sapphire substrate, and a convex portion that is formed on the principal surface, has a cone or pyramid shape or a truncated cone or pyramid shape, is disposed to form a lattice pattern in a top view thereof, and includes a side surface inclined at an angle of less than 90 degrees relative to the principal surface. The convex portion has a height of 0.5 to 3 μm from the principal surface. A distance between adjacent ones of the convex portion is 1 to 6 μm. The side surface of the convex portion has a surface roughness (RMS) of not more than 10 nm.

The present application is based on Japanese patent application No.2011-228307 filed on Oct. 17, 2011, the entire contents of which are incorporated herein by reference.

### BACKGROUND OF THE INVENTION

1. FIELD OF THE INVENTION

This invention relates to a nitride semiconductor growth substrate that is capable of growing a nitride semiconductor with a low dislocation density and a manufacturing method of the nitride semiconductor growth substrate. This invention also relates to a nitride semiconductor epitaxial substrate and a nitride semiconductor element that are manufactured by using the nitride semiconductor growth substrate.

2. DESCRIPTION OF THE RELATED ART

In a GaN based LED, as a means for improving a light-extraction efficiency, a method is known that a processing for forming a concavo-convex shape such as a cone shape, a truncated pyramid shape is applied to a surface (growth surface) of a sapphire substrate, a GaN layer is epitaxially grown on a surface of the concavo-convex shape until the surface of the GaN layer is planarized, and an epitaxial layer including a light emitting layer is formed on the GaN layer (for example, refer to JP-A-2002-280611 and JP-A-2011-91374).

### SUMMARY OF THE INVENTION

When GaN is grown on the surface of the concavo-convex shape of the above-mentioned sapphire substrate, the island growth during the initial GaN growth can be accelerated such that dislocations are associated and eliminated each other. Thus the GaN layer can have a lower dislocation density as compared to the GaN growth on a flat surface of a sapphire substrate.

While the above-mentioned GaN growth on the surface of the concavo-convex shape of the sapphire substrate can reduce the dislocation, it is not sufficient yet, thus a method that is capable of realizing further reduction of dislocation is required.

Accordingly, it is an object of the invention to provide a nitride semiconductor growth substrate that is capable of growing a nitride semiconductor having a low dislocation density and a manufacturing method of the same, and a nitride semiconductor epitaxial substrate and a nitride semiconductor element that are manufactured by using the nitride semiconductor growth substrate.

(1) According to one embodiment of the invention, a nitride semiconductor growth substrate comprises:

a principal surface comprising a C-plane of a sapphire substrate; and

a convex portion that is formed on the principal surface, has a cone or pyramid shape or a truncated cone or pyramid shape, is disposed to form a lattice pattern in a top view thereof, and comprises a side surface inclined at an angle of less than 90 degrees relative to the principal surface,

wherein the convex portion has a height of 0.5 to 3 μm from the principal surface,

wherein a distance between adjacent ones of the convex portion is 1 to 6 μm, and

wherein the side surface of the convex portion has a surface roughness (RMS: root mean square) of not more than 10 nm.

(2) According to another embodiment of the invention, a manufacturing method of a nitride semiconductor growth substrate comprises:

forming a convex portion on a principal surface comprising a C-plane of a sapphire substrate by photolithography or dry etching such that the convex portion has a cone or pyramid shape or a truncated cone or pyramid shape, is disposed to form a lattice pattern in a top view thereof, and comprises a side surface inclined at an angle of less than 90 degrees relative to the principal surface, wherein the convex portion has a height of 0.5 to 3 μm from the principal surface, a distance between adjacent ones of the convex portion is 1 to 6 μm, and the side surface of the convex portion has a surface roughness (RMS) of not more than 10 nm; and

annealing the sapphire substrate in an atmosphere including oxygen so as to planarize the side surface of the convex portion such that a surface roughness (RMS) of the side surface is not more than 10 nm,

(3) According to another embodiment of the invention, a nitride semiconductor epitaxial substrate comprises:

the nitride semiconductor growth substrate according to the above embodiment (1); and

an epitaxial layer comprising a nitride semiconductor formed on the nitride semiconductor growth substrate such that it is grown until a surface thereof is planarized.

(4) According to another embodiment of the invention, a nitride semiconductor element comprises:

the nitride semiconductor epitaxial substrate according to the above embodiment (3); and

an element structure formed on the nitride semiconductor epitaxial substrate.

### Points of the Invention

According to one embodiment of the invention, a nitride semiconductor growth sapphire substrate is configured such that the surface roughness (RMS) of the side surface of the convex portion is planarized so as to be not more than 10 nm, thus the raw material gases are not likely to adhere to the inclined side surface of the convex portion as a surface other than the C-plane. Therefore, GaN nuclei are not likely to be generated or grown on the planarized side surface so that the dislocation density in the GaN layer grown on the substrate can be reduced significantly.

### BRIEF DESCRIPTION OF THE DRAWINGS

The preferred embodiments according to the invention will be explained below referring to the drawings, wherein:

FIG. 1A is a side view schematically showing a nitride semiconductor growth substrate according to an embodiment of the invention;

FIG. 1B is a partial enlarged plan view of a principal surface shown in FIG. 1A;

FIG. 1C is a cross-sectional view taken along the line C-C in FIG. 1B;

FIGS. 2A to 2D are cross-sectional views respectively showing a series of manufacturing steps in the manufacturing method of the nitride semiconductor growth substrate according to an embodiment of the invention;

FIG. 3 is a cross-sectional view schematically showing a nitride semiconductor epitaxial substrate of Comparative Example;

FIG. 4 is a cross-sectional view schematically showing a nitride semiconductor epitaxial substrate according to an embodiment of the invention;

FIG. 5 is a cross-sectional view schematically showing a rough configuration of a nitride semiconductor element according to an embodiment of the invention; and

FIG. 6 is a cross-sectional view schematically showing a nitride semiconductor epitaxial substrate according to another embodiment of the invention.

### DETAILED DESCRIPTION OF THE PREFERRED EMBODIMENTS

The invention has been achieved based on knowledge that when a processing for forming a concavo-convex shape such as a cone shape is applied to a principal surface (C-plane) of a sapphire substrate, and a nitride semiconductor such as a GaN layer is epitaxially grown on the principal surface processed to form the concavo-convex shape, an effect of reducing the dislocation of the nitride semiconductor is dependent on a surface roughness of an inclined side surface of the concavo-convex shape, and planarization is realized such that a value of the surface roughness (RMS: root mean square) of the side surface is not more than 10 nm, thereby reduction of dislocation can be accelerated.

A nitride semiconductor growth substrate and a manufacturing method of the nitride semiconductor growth substrate, and a nitride semiconductor epitaxial substrate and a nitride semiconductor element manufactured by using the nitride semiconductor growth substrate according to an embodiment of the invention will be explained below.

### Nitride Semiconductor Growth Substrate

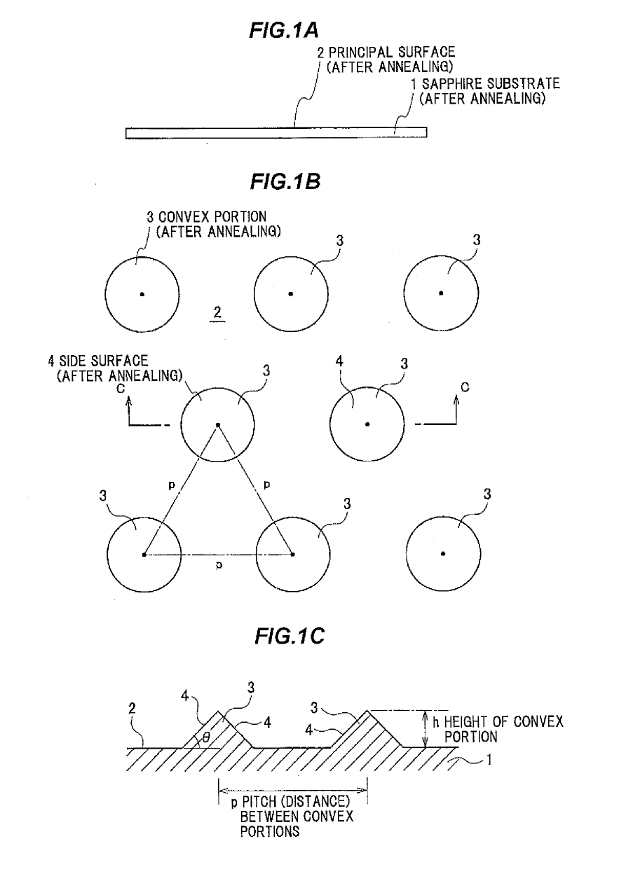

FIG. 1A is a side view schematically showing a nitride semiconductor growth substrate according to an embodiment of the invention, FIG. 1B is a partial enlarged plan view of a principal surface shown in FIG. 1A and FIG. 1C is a cross-sectional view taken along the line C-C in FIG. 1B.

As shown in FIG. 1A, a sapphire substrate 1 as a nitride semiconductor growth substrate is a wafer composed of sapphire having a discoid shape or the like, and to a principal surface 2 that is a C-plane to be a growth surface of the sapphire substrate 1 that grows a nitride semiconductor thereon, a processing for forming a concavo-convex shape that is effective for reduction of dislocation is applied.

As shown in FIGS. 1B and 1C, a convex portion 3 having a cone shape is formed on the principal surface 2 of the sapphire substrate 1 so as to be disposed in a triangle lattice shape. The convex portion 3 has a height of 0.5 to 3 μm from the principal surface 2, and a pitch (a distance, a length of a side of an equilateral triangle of the triangle lattice) (p) between the convex portions 3 adjacent to each other is 1 to 6 μm. The convex portion 3 has a side surface (conical surface) 4 having an inclination angle θ inclined at an angle of less than 90 degrees relative to the principal surface 2. It is preferable that the inclination angle θ of the side surface 4 is 30 to 70 degrees.

The side surface 4 of the convex portion 3 is configured to have a flat surface such that a value of a surface roughness (RMS: Root Mean Square) thereof is not more than 10 nm. It is preferable that the surface roughness (RMS) of the side surface 4 of the convex portion 3 is not more than 3 nm, The planarization of side surface 4 of the convex portion 3 can be carried out by, for example, forming the convex portion 3 by dry etching, and then applying an annealing treatment thereto in an atmosphere including oxygen.

The convex portion 3 used in the embodiment has a cone shape, but not limited to this, it can have a pyramid shape (such as a triangular pyramid shape, a quadrangular pyramid shape), an elliptic cone shape or the like. In addition, as shown in FIG. 1C, the convex portion 3 used in the embodiment has a cone shape in which the inclination angle θ of the side surface 4 is approximately constant, but not limited to this, it can also have the cone shape, the pyramid shape or the elliptic cone shape in which the inclination angle of the side surface is not constant, and the side surface expands outward or shrinks inward (for example, a paraboloid surface shape or a hyperboloid surface shape that is formed by that a side surface (conical surface) of a convex portion of a cone shape expands outward or shrinks inward). Furthermore, the convex portion formed in the principal surface 2 of the sapphire substrate 1 can have a truncated cone or pyramid shape. The truncated cone or pyramid shape includes a truncated cone shape, a truncated pyramid shape (such as a truncated triangular pyramid shape, a truncated quadrangular pyramid shape) and a truncated elliptic cone shape, and it can also have the truncated cone or pyramid shape in which the side surface expands outward or shrinks inward.

In addition, the convex portion 3 is disposed on the principal surface 2 in a triangle lattice shape, but not limited to the triangle lattice shape, it can be disposed in a lattice shape such as a square lattice shape, and it is preferable that the convex portion 3 is decentrally and uniformly disposed on the principal surface 2.

### Manufacturing Method of the Nitride Semiconductor Growth Substrate

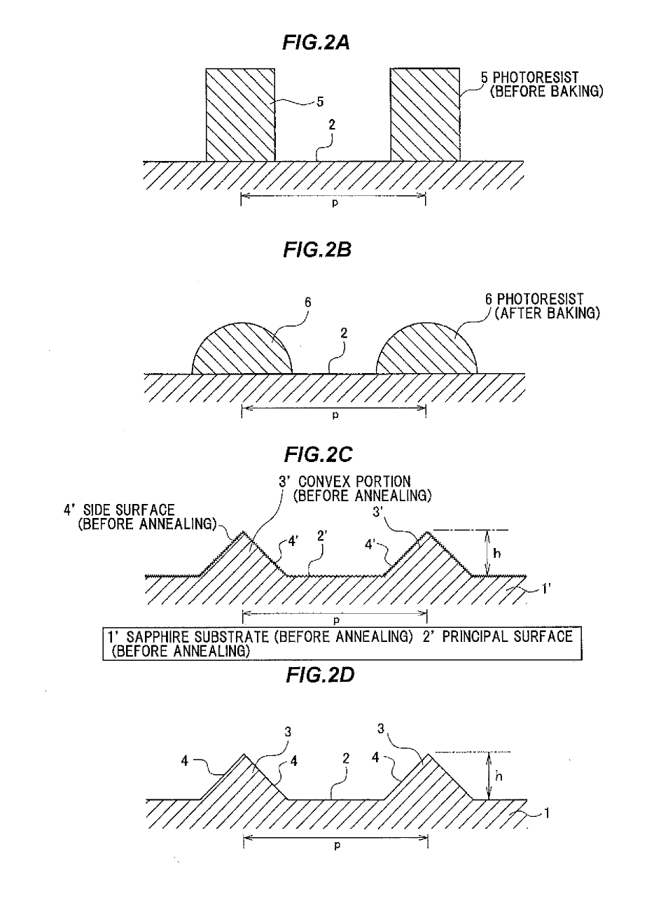

Next, a manufacturing method of the nitride semiconductor growth substrate according to an embodiment of the invention will be explained. FIGS. 2A to 2D are cross-sectional views respectively showing a series of manufacturing steps in the manufacturing method of the nitride semiconductor growth substrate according to the embodiment. The nitride semiconductor growth substrate according to the embodiment is a substrate formed by disposing convex portions having a cone shape on a principal surface that is a C-plane of a sapphire substrate in a triangle lattice shape.

First, a photoresist pattern is formed on the principal surface 2 that is a C-plane of the sapphire substrate 1. As an example, a photoresist is coated on the whole surface of the principal surface 2 of the C-plane sapphire substrate to which mirror polishing is applied, and then a pattern exposure and development are carried out by photolithography, so as to form a photoresist pattern configured such that photoresists 5 having a columnar shape are disposed on the principal surface 2 in a triangle lattice shape (FIG. 2A). A pitch (p) between the photoresists 5, 5 having a columnar shape adjacent to each other (this pitch (p) becomes a pitch (p) between convex portions of a sapphire substrate formed by subsequent dry etching process) is configured to be 1 to 6 μm.

Next, the sapphire substrate in which the photoresist pattern is formed is baked by using a hot plate, so as to heat the photoresists. In the baking process, an excess organic solvent in the photoresist 5 is vaporized, and simultaneously the photoresist 5 having a columnar shape is changed to a photoresist 6 having a hemispherical shape (FIG. 2B).

Next, a dry etching is applied to the principal surface 2 of the sapphire substrate 1 on which the photoresist 6 having a hemispherical shape is formed. The dry etching process is configured such that, as an example, a plasma etching device is used, the sapphire substrate 1 is disposed in a reacting room of the plasma etching device, a reactive gas including chlorine is supplied into the reacting room, so that the dry etching is applied to the principal surface 2 of the sapphire substrate 1. By the dry etching, a convex portion 3′ having a cone shape is formed on a principal surface 2′ of a sapphire substrate 1′ so as to be disposed in a triangle lattice shape (FIG. 2C). The convex portion 3′ has a height of 0.5 to 3 μm from the principal surface 2′, and a pitch (p) between the convex portions 3′, 3′ adjacent to each other is 1 to 6 μm. However, the side surface 4′ of the convex portion 3′ having a cone shape and the surface of the principal surface 2′ become roughened by the dry etching, a value of the surface roughness (RMS) becomes approximately more than 10 nm and not more than 50 nm.

Next, an annealing is applied to the sapphire substrate 1′ in which a great number of convex portions 3′ are disposed in a triangle lattice shape by the dry etching. The annealing process is configured such that, as an example, an electric furnace is used, the sapphire substrate 1′ is disposed in the electric furnace, the electric furnace is internally configured to be in an atmosphere including oxygen (in an oxygen atmosphere or in the air), and an annealing treatment is carried out at an annealing temperature of 800 to 1200 degrees C. for not less than 1 hour (FIG. 2D). By the annealing treatment, the side surface 4′ of the convex portion 3′ and the principal surface 2′ are planarized, thus a value of the surface roughness (RMS) of the side surface 4 of the convex portion 3 and the principal surface 2 after annealing becomes not more than 10 nm. In this way, the sapphire substrate 1 that is the nitride semiconductor growth substrate according to the embodiment can be obtained. The value of the surface roughness (RMS) of the side surface 4 and the principal surface 2 after annealing is reduced in proportion to the height of the annealing temperature and the length of the annealing treatment time, in the best case, the surface roughness (RMS) of 0.2 nm is obtained. The value of the surface roughness (RMS) is a value obtained by using an Atomic Force Microscope: AFM). Further, for example, an exposure condition and/or a baking condition are/is adjusted so as to realize a change from the photoresist 6 having a hemispherical shape to a photoresist having a semi-ellipsoid shape, thereby the inclination angle θ of the side surface 4 of the convex portion 3 having a cone shape can be adjusted and changed.

### Nitride Semiconductor Epitaxial Substrate

The nitride semiconductor epitaxial substrate according to an embodiment of the invention is formed by growing a GaN layer as an epitaxial layer comprised of a nitride semiconductor on the above-mentioned sapphire substrate 1 to which an annealing treatment is applied, until the surface thereof is planarized.

### Comparative Example

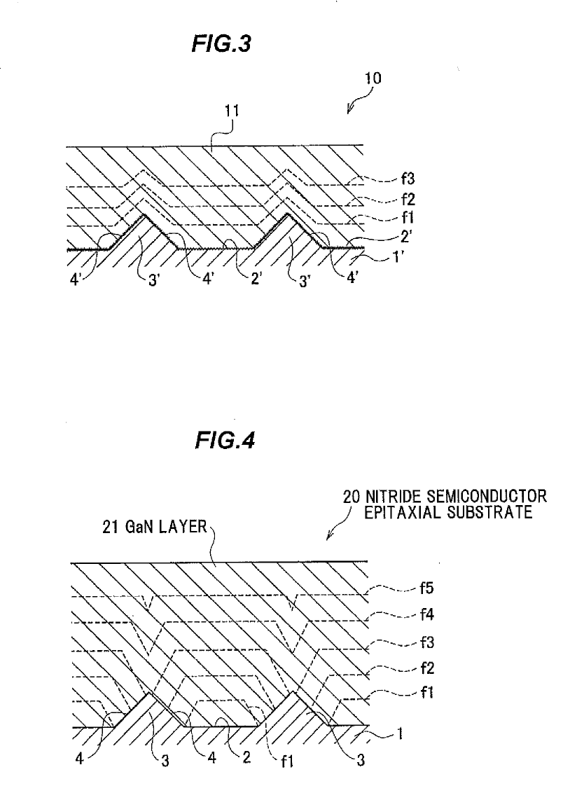

First, as Comparative Example for comparing with the nitride semiconductor epitaxial substrate according to the embodiment, a GaN layer was grown by using the sapphire substrate before annealing shown in FIG. 2C, namely the sapphire substrate 1′ configured such that a surface roughness (RMS) of the side surface 4′ of the convex portion 3′ having a cone shape and the principal surface 2′ is 10 to 50 nm. FIG. 3 shows a nitride semiconductor epitaxial substrate 10 of Comparative Example.

The growth of the GaN layer 11 on the sapphire substrate 1′ was carried out by HYPE (hydride vapor phase epitaxy). As a growth condition, a pressure in the HYPE device of 10 to 120 kPa and a growth temperature of 800 to 1200 degrees C. were used, and a GaCl gas as a Ga raw material, a NH₃ gas as a nitrogen raw material gas and a mixture gas of H₂ and N₂ as a carrier gas were used.

In case of the growth of the GaN layer 11 on the sapphire substrate 1′, the raw material gases are likely to adhere to the principal surface 2′ of the C-plane, thus GaN nuclei are easily generated. On the other hand, generally the raw material gases are not likely to adhere to the side surface 4′ inclined of the convex portion 3′ that is a surface other than the C-plane, thus GaN nuclei are not likely to be generated. However, the side surface 4′ of the convex portion 3′ in the sapphire substrate 1′ of Comparative Example has a surface roughness (RMS) that is coarser such as 10 to 50 nm, consequently the raw material gases are likely to adhere thereto, thus relatively GaN nuclei are easily generated. Accordingly, from an early period of the GaN growth, GaN is grown from the whole surface of the sapphire substrate 1′, as shown by broken lines in FIG. 3, the GaN growth surface (f1) in the early period of the growth is formed to have a shape corresponding to the surface of the sapphire substrate 1′. The GaN growth surface is sequentially grown as the surfaces (f1), (f2) and (f3), so as to become a flat growth surface soon. The inclined planes not parallel to the C-plane in the GaN growth surface fold dislocations so as to accelerate association and elimination of the dislocations, but in case of the GaN layer 11 of Comparative Example, a period when the inclined plane of the growth surface exists is short so as to become a flat growth surface soon, thus it has less dislocation-reduction effect. Further, even if the principal surface 2′ that is a C-plane is a flat surface such that the surface roughness (RMS) is not more than 10 nm or is not a flat surface such that the surface roughness (RMS) is more than 10 nm and not more than 50 nm, there is no significant difference in the GaN growth.

### Example of the Invention

The nitride semiconductor epitaxial substrate of the embodiment was formed by using the above-mentioned sapphire substrate 1 to which an annealing treatment is applied shown in FIG. 2D, namely the sapphire substrate 1 configured such that the surface roughness (RMS) of the side surface 4 of the convex portion 3 having a cone shape and the principal surface 2 is not more than 10 nm, so as to grow a GaN layer 21. FIG. 4 shows a nitride semiconductor epitaxial substrate 20 according to the embodiment of the invention. The growth of the GaN layer 21 on the sapphire substrate 1 was carried out by HYPE method similarly to the above-mentioned Comparative Example under the same growth condition as Comparative Example.

The sapphire substrate 1 of the embodiment is configured differently from Comparative Example such that the surface roughness (RMS) of the side surface 4 of the convex portion 3 is planarized so as to be not more than 10 nm, thus the raw material gases are not likely to adhere to the side surface 4 inclined of the convex portion 3 that is as a surface other than the C-plane, consequently GaN nuclei are not likely to be generated. Namely, the GaN nuclei are generated in the principal surface 2 and are hardly generated in the side surface 4, consequently GaN is grown on the principal surface 2 that is a C-plane in the early period of the growth, thus the GaN growth surface (f1) in the early period of the growth is formed to have a shape shown by broken lines in FIG. 4. The GaN layer of the GaN growth surface (f1) growing on the principal surface 2 is grown while being expanded in such a way that it buries the convex portion 3 so as to form growth surfaces (f2), (f3), in addition, it becomes a GaN layer of a continuous growth surface (f4) that has a pit located above the convex portion 3, and then it is grown while reducing the scale of the pit of the growth surface, so as to finally form a GaN layer 21 having a flat surface.

In case of the nitride semiconductor epitaxial substrate 20 according to the embodiment, the GaN growth on the inclined side surface 4 is delayed than the GaN growth on the principal surface 2 that is a C-plane. Consequently, a period when the inclined planes not parallel to the C-plane in the GaN growth surfaces (f1) (f2) . . . exist becomes long, thus dislocations are folded at the inclined planes of the growth surface so as to accelerate association and elimination of the dislocations. Accordingly, in the embodiment, the dislocation density of the GaN layer 21 can be reduced in a low level, thus the nitride semiconductor epitaxial substrate 20 including the GaN layer 21 having a good crystalline quality can be obtained.

Even if the surface roughness (RMS) of the side surface 4 of the convex portion 3 is planarized so as to be not more than 10 nm, if the height (h) of the convex portion 3 is shortened than 0.5 μm or the pitch (p) between the convex portions 3 adjacent to each other is enlarged to more than 6 μm, it comes close to the conventional case that the GaN growth is carried out by using a flat sapphire substrate to which the processing for forming a concavo-convex shape is not applied, thus the dislocation-reduction effect due to the fact that the inclined planes of the GaN growth surface exist cannot be obtained. In addition, if the height (h) of the convex portion 3 is heightened than 3 μm, it becomes difficult to planarize the surface of the nitride semiconductor layer such as the GaN layer that is grown on the sapphire substrate.

A specific example of measurement of dislocation density of a GaN layer surface of a nitride semiconductor epitaxial substrate will be explained below.

The dislocation density of a GaN layer surface of a nitride semiconductor epitaxial substrate was measured in relation to the respective cases that are a conventional case that a flat sapphire substrate (surface roughness (RMS) of principal surface is not more than 1 nm) to which the processing for forming a concavo-convex shape is not applied is used, a case of the above-mentioned Comparative Example that the surface roughness (RMS) of the side surface 4′ of the convex portion 3′ is 10 to 50 nm and a case of the above-mentioned embodiment that the surface roughness (RMS) of the side surface 4 of the convex portion 3 having a cone shape is not more than 10 nm. Further, in Comparative Example and the embodiment, the height (h) of the convex portion from the principal surface was configured to be 1 μm and the pitch (p) between the convex portions adjacent to each other was configured to be 4 μm.

The GaN layer on the conventional flat sapphire substrate has a dislocation density of 3×10⁸/cm², the GaN layer on the sapphire substrate of the Comparative Example has a dislocation density of more than 2×10⁸/cm², and if the surface roughness (RMS) is 50 nm, it has a dislocation density of 2.5×10⁸/c². In addition, the GaN layer on the sapphire substrate of the embodiment has a dislocation density of 2×10⁸/cm², if the surface roughness (RMS) of the side surface of the convex portion is 10 nm, similarly if the surface roughness (RMS) is 3 nm, it has a dislocation density of 1.2×10⁸/cm², and similarly if the surface roughness (RMS) is 0.2 nm, it has a dislocation density of 0.5×10⁸/cm².

In addition, the dislocation density of the surface of the GaN layer formed on the sapphire substrate was measured in relation to the respective cases that the pitch (p) between the convex portions 3 having a cone shape that is formed on the principal surface of the sapphire substrate was variously changed in the range of 0.5 to 6.5 μm, the height (h) of the convex portion 3 was variously changed in the range of 0.2 to 3.1 μm, and the surface roughness (RMS) of the side surface 4 of the convex portion 3 was configured to be 10 nm, 3 nm and 0.2 nm. Further, the inclination angle θ of the side surface 4 of the convex portion 3 was configured to be approximately 45 degrees.

Tables 1 to 3 show the measurement result of the dislocation density (×10⁸/cm²). Table 1 shows a case that the surface roughness (RMS) of the side surface 4 is 10 nm, Table 2 shows a case that the surface roughness (RMS) of the side surface 4 is 3 nm, and Table 3 shows a case that the surface roughness (RMS) of the side surface 4 is 0.2 nm. Further, as shown in Tables 1 to 3, the convex portions 3 were fabricated in the range that the convex portions 3 adjacent to each other that are formed on the principal surface of the sapphire substrate are not overlapped with each other even if only partially.

TABLE 1

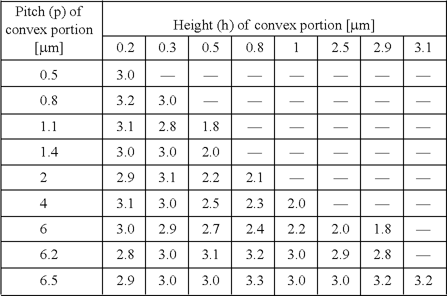

TABLE 2

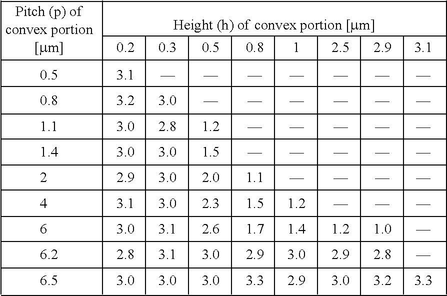

TABLE 3

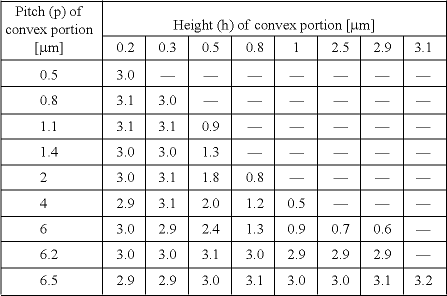

As shown Tables 1 to 3, it is recognized that the nitride semiconductor epitaxial substrates according to the embodiment (the shaded areas in Tables 1 to 3) satisfying the conditions that the surface roughness (RMS) of the side surface 4 of the convex portion 3 is not more than 10 nm, the height (h) of the convex portion 3 is 0.5 to 3 μm and the pitch (distance) (p) between the convex portions 3 adjacent to each other is 1 to 6 μm have a dislocation density reduced in a low level. In addition, it is recognized that the dislocation density is reduced in proportion to the smallness of the value of the surface roughness (RMS) of the side surface 4, namely the flatness of the side surface 4. Furthermore, it is recognized that the dislocation density is reduced in proportion to the smallness of the occupancy rate of the principal surface 2 that is a C-plane of the surface of the sapphire substrate,

### Nitride Semiconductor Element

The nitride semiconductor element according to the embodiment is a nitride semiconductor element manufactured by using the above-mentioned nitride semiconductor epitaxial substrate 20 according to the embodiment and forming element structures such as a nitride semiconductor layer, an electrode in the nitride semiconductor epitaxial substrate 20. The surface of the nitride semiconductor layer 21 of the above-mentioned nitride semiconductor epitaxial substrate 20 according to the embodiment has a low dislocation density, thus the nitride semiconductor element having excellent characteristics can be manufactured.

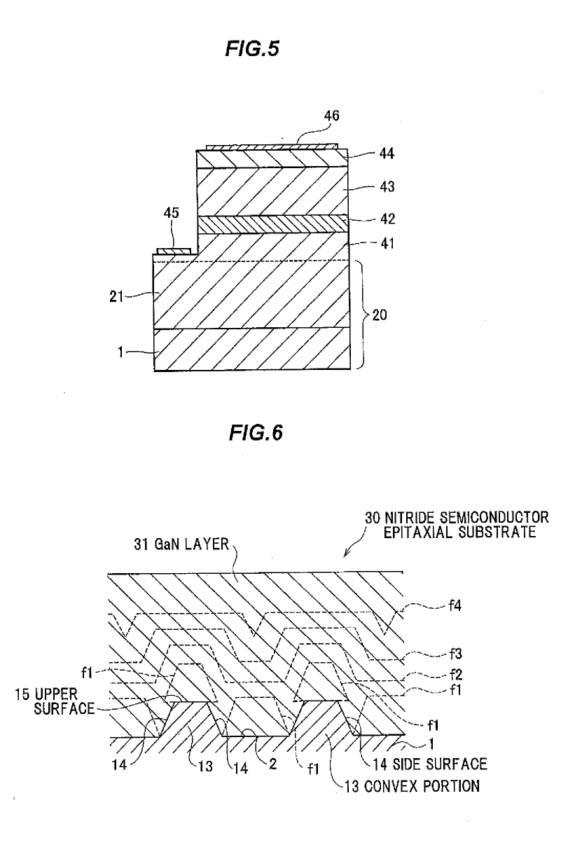

As an example of the nitride semiconductor element, a blue Light Emitting Diode (a blue LED) shown in FIG. 5 that is manufactured by using the above-mentioned nitride semiconductor epitaxial substrate 20 according to the embodiment will be explained.

The nitride semiconductor epitaxial substrate 20 is disposed in a MOVPE device and a laminated semiconductor having a blue LED structure is grown on the nitride semiconductor epitaxial substrate 20. The laminated semiconductor having a blue LED structure is comprised of an n-type GaN cladding layer 41, an active layer 42 having an InGaN/GaN multiple quantum well structure, a p-type AlGaN cladding layer 43 and a p-type GaN contact layer 44 that are sequentially laminated on the GaN layer 21 so as to be grown.

After the above-mentioned laminated semiconductor is grown, a substrate for LED is extracted from the MOVPE device, the laminated semiconductor layer of the substrate for LED obtained is partially removed by Reactive Ion Etching (RIE) so that a part of the n-type GaN cladding layer 41 is exposed. An n-side electrode 45 is formed on the n-type GaN cladding layer 41 exposed and simultaneously a p-side electrode 46 is formed on the p-type GaN contact layer 44, after that a chipping operation and the like are carried out, thereby the blue LED having a structure shown in FIG. 5 is manufactured. The LED manufactured by laminating the n-type GaN cladding layer 41, the active layer 42, the p-type AlGaN cladding layer 43 and the like on the GaN layer 21 having a good crystalline quality of the nitride semiconductor epitaxial substrate 20 has a large light output, so that reliability can be enhanced.

### Other Embodiments

Next, a nitride semiconductor growth substrate and a manufacturing method of the nitride semiconductor growth substrate, and a nitride semiconductor epitaxial substrate manufactured by using the nitride semiconductor growth substrate according to another embodiment of the invention will be explained. FIG. 6 shows a cross-sectional view of the nitride semiconductor epitaxial substrate according to another embodiment of the invention.

The sapphire substrate 1 as a nitride semiconductor growth substrate used in the nitride semiconductor epitaxial substrate 30 according to the embodiment is, as shown in FIG. 6, is formed such that convex portions 13 having a truncated cone shape are disposed on the principal surface 2 that is a C-plane in a triangle lattice shape. The height from the principal surface 2 to the upper surface 15 of the convex portions 13 having a truncated cone shape is 0.5 to 3 μm and the pitch between the convex portions 13 adjacent to each other is 1 to 6 μm. A side surface 14 is inclined at a predetermined inclination angle of less than 90 degrees relative to the principal surface 2, and it is preferable that the inclination angle of the side surface 14 is 30 to 70 degrees. In addition, the side surface 14 of the convex portion 13 is configured to have a flat surface such that a value of the surface roughness (RMS) thereof is not more than 10 nm.

Next, a manufacturing method the nitride semiconductor growth substrate according to the embodiment will be briefly explained.

First, a photoresist is coated on the whole surface of the principal surface that is a C-plane of the sapphire substrate 1, and then a pattern exposure and development are carried out by photolithography, thereby a photoresist pattern is formed on the principal surface. Next, a dry etching is applied to the principal surface of the sapphire substrate 1 on which the photoresist pattern is formed, by using a plasma etching device. The etching time of dry etching is configured to be shorter than that of the above-mentioned embodiment, thereby the convex portions 13 having a truncated cone shape are formed under the photoresist. Next, after the photoresist is removed, by using an electronic furnace, an annealing treatment is applied to the sapphire substrate 1 in which a great number of the convex portions are formed by dry etching. The annealing treatment is carried out in an atmosphere including oxygen of the inside of the electric furnace, at the temperature of 800 to 1200 degrees C., and for not less than 1 hour. By the annealing treatment, the side surface of the convex portion having a truncated cone shape and the principal surface that have the surface roughness (RMS) of more than 10 nm are planarized, thus a value of the surface roughness (RMS) of the side surface 14 of the convex portion 13 and the principal surface 2 after annealing becomes not more than 10 nm (further, the upper surface 15 of the convex portion 13 is covered by the photoresist, thus it is not subjected to dry etching so as to remain a flat surface). In this way, the sapphire substrate 1 according to the embodiment can be obtained, in which the convex portions 13 having a truncated cone shape and comprised of a flat surface are formed.

Further, for example, the photoresist is configured to have a truncated cone shape, the inclination angle of the side surface thereof is changed or the condition of dry etching is adjusted, thereby the inclination angle of the side surface 14 of the convex portion 13 having a truncated cone shape can be adjusted and changed.

As shown in FIG. 6, the nitride semiconductor epitaxial substrate 30 is formed by that the GaN layer 31 is grown on the sapphire substrate 1 having the convex portion 13 having a truncated cone shape that is planarized by the above-mentioned annealing treatment, until the surface of the GaN layer 31 is planarized.

The growth of the GaN layer 31 on the sapphire substrate 1 was carried out by HYPE method. The sapphire substrate 1 is configured such that the surface roughness (RMS) of the side surface 14 of the convex portion 13 is planarized so as to be not more than 10 nm, thus the raw material gases are not likely to adhere to the side surface 14 inclined that is a surface other than the C-plane, consequently GaN nuclei are not likely to be generated. Namely, the GaN nuclei are generated in the principal surface 2 and the upper surface 15 of the convex portion 13 and are hardly generated in the side surface 14, consequently GaN is grown on the principal surface 2 and the upper surface 15 of the convex portion 13 that is a C-plane in the early period of the growth, thus the GaN growth surface (f1) in the early period of the growth is formed to have a shape shown by broken lines in FIG. 6. The GaN layers of the GaN growth surface (f1) growing on the principal surface 2 and the upper surface 15 of the convex portion 13 are grown while being expanded and are combined with each other, so as to become a GaN layer that has a GaN growth surface (f2) of a convex shape located above the convex portion 13, and further the GaN layers are grown while planarizing the GaN growth surface of a convex shape (growth surfaces (f3), (f4)), so as to finally form a GaN layer 31 having a flat surface.

In case of the nitride semiconductor epitaxial substrate 30 according to the embodiment, the GaN growth on the inclined side surface 14 is delayed than the GaN growth on the principal surface 2 and the upper surface 15 of the convex portion 13 that are a C-plane. Consequently, a period when the inclined planes not parallel to the C-plane in the GaN growth surfaces exist becomes long, thus dislocations are folded at the inclined planes of the growth surface, so that association and elimination of the dislocations occur frequently. Accordingly, in the embodiment, the dislocation density of the GaN layer 31 can be also reduced in a low level, thus the nitride semiconductor epitaxial substrate 30 including the GaN layer 31 having a low dislocation density can be obtained.

By using the nitride semiconductor epitaxial substrate 30 according to the embodiment, a LED structure was formed on the nitride semiconductor epitaxial substrate 30, so as to manufacture a LED, and the LED that has a large light output and a high reliability could be obtained.

In addition, a sapphire substrate configured such that the convex portion 3 and the convex portion 13 similar to those used in the above-mentioned embodiments are disposed on the principal surface 2 in a square lattice shape was manufactured, and by using the sapphire substrate in which the convex portions are disposed in a square lattice shape, a nitride semiconductor epitaxial substrate and a nitride semiconductor element were manufactured, and an excellent result similar to that in the above-mentioned embodiments could be obtained.

Further, in the above-mentioned embodiments, HYPE method was used for the vapor phase growth of GaN that is a nitride semiconductor on the sapphire substrate, but not limited to this, MOVPE method or the like can be also used. In addition, in the nitride semiconductor epitaxial substrates according to the above-mentioned embodiments, GaN (a GaN layer) was grown as the nitride semiconductor (nitride semiconductor layer) on the sapphire substrate, but not limited to this, AIN, InN, AlGaN, InGaN or the like can be also grown, or it can be also adopted to combine a plurality of epitaxial layers that have a different composition with each other and are selected from the nitride semiconductors, and to laminate the epitaxial layers.

In addition, the mask used when the convex portions are formed by applying the dry etching to the principal surface of the sapphire substrate is not limited to the photoresist, and the planarization of the side surface of the convex portion on the principal surface is not limited to the annealing treatment, but any method can be used if it is capable of planarizing such that the surface roughness (RMS) of the side surface is not more than 10 nm.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A nitride semiconductor growth substrate, comprising:
a principal surface comprising a C-plane of a sapphire substrate; and
a convex portion that is formed on the principal surface, has a cone or pyramid shape or a truncated cone or pyramid shape, is disposed to form a lattice pattern in a top view thereof, and comprises a side surface inclined at an angle of less than 90 degrees relative to the principal surface,
wherein the convex portion has a height of 0.5 to 3 μm from the principal surface,
wherein a distance between adjacent ones of the convex portion is 1 to 6 μm, and
wherein the side surface of the convex portion has a surface roughness (RMS) of not more than 10 nm.

2. A manufacturing method of a nitride semiconductor growth substrate, comprising:
forming a convex portion on a principal surface comprising a C-plane of a sapphire substrate by photolithography or dry etching such that the convex portion has a cone or pyramid shape or a truncated cone or pyramid shape, is disposed to form a lattice pattern in a top view thereof, and comprises a side surface inclined at an angle of less than 90 degrees relative to the principal surface, wherein the convex portion has a height of 0.5 to 3 μm from the principal surface, a distance between adjacent ones of the convex portion is 1 to 6 μm, and the side surface of the convex portion has a surface roughness (RMS) of not more than 10 nm; and
annealing the sapphire substrate in an atmosphere including oxygen so as to planarize the side surface of the convex portion such that a surface roughness (RMS) of the side surface is not more than 10 nm.

3. A nitride semiconductor epitaxial substrate, comprising:
the nitride semiconductor growth substrate according to claim 1; and
an epitaxial layer comprising a nitride semiconductor formed on the nitride semiconductor growth substrate such that it is grown until a surface thereof is planarized.

4. A nitride semiconductor element, comprising:
the nitride semiconductor epitaxial substrate according to claim 3; and
an element structure formed on the nitride semiconductor epitaxial substrate.
